(19) United States
(12) Patent Application Publication
(10) Pub. No.: US 2015/0221794 A1
(43) Pub. Date: Aug. 6, 2015

(54) MIXED BISMUTH AND COPPER OXIDES AND SULPHIDES FOR PHOTOVOLTAIC USE

(71) Applicants: RHODIA OPERATIONDS, Aubervilliers (FR); CENTRE NATIONAL DE LA RECHERCHE SCIENTIFIQUE, Paris (FR)

(72) Inventors: Thierry Le Mercier, Rosny Sous Bois (FR); Philippe Barboux, L'Hay Les Roses (FR); Tangui Le Bahers, Villefranche sur Saone (FR)

(21) Appl. No.: 14/429,474

(22) PCT Filed: Sep. 30, 2013
(86) PCT No.: PCT/EP2013/070350

§ 371 Date: Mar. 19, 2015

(30) Foreign Application Priority Data
Sep. 28, 2012 (FR) 1202589

(51) Int. Cl. H01L 31/032; H01L 31/0272; C01G 29/00

(52) U.S. Cl. CPC H01L 31/032; C01G 29/006; H01L 31/0272; C01P 2006/40

(57) ABSTRACT

The present invention relates to the use of a material comprising at least one compound of formula (I): BiCu_{1-z}OₐS_{b}Se_{c}Te_{d} (I), where 0≦z≦0.2; 0≦a≦2; 0≦b≦2; 0≦c≦2; 0≦d≦2; and a+b+c+d=2, as a p-type semiconductor, for providing a photocurrent. The invention also relates to the photovoltaic devices using these semiconductors.

The present invention relates to the field of mineral compounds intended for providing a photocurrent, especially via a photovoltaic effect.

Nowadays, photovoltaic technologies using mineral compounds are mainly based on silicon technologies (more than 80% of the market) and on “thin layer” technologies (mainly CdTe and GIGS (Copper Indium Gallium Selenium), representing 20% of the market). The growth of the photovoltaic market appears to be exponential (40 GW cumulative in 2010, 67 GW cumulative in 2011).

Unfortunately, these technologies suffer from drawbacks that limit their capacity to satisfy this growing market. These drawbacks include poor flexibility as regards silicon from a mechanical and installation viewpoint, and the toxicity and scarcity of the elements for the “thin layer” technologies. In particular, cadmium, tellurium and selenium are toxic. Moreover, indium and tellurium are rare, which has an impact especially on their cost.

For these reasons, it is sought to dispense as much as possible with the use of indium, cadmium, tellurium and selenium.

One route that has been recommended for replacing indium in CIGS is to replace it with the couple (Zn²⁺, Sn⁴⁺). In this context, the compound Cu₂ZnSnSeₐ (known as CZTS) has especially been proposed. This material is nowadays considered as being the most serious successor to GIGS in terms of efficacy, but has the drawback of the toxicity of the selenium.

As regards selenium and tellurium, few replacement solutions have been proposed, and they generally prove to be disadvantageous. Compounds such as SnS, FeS₂ and Cu₂S have indeed been tested, but, although they have advantageous intrinsic properties (gap, conductivity, etc.), they do not prove to be sufficiently chemically stable (e.g.: Cu₂S is very readily transformed into Cu₂O on contact with air and moisture).

To the inventors' knowledge, no satisfactory solution for obtaining good photovoltaic efficacy without problems associated with the toxicity and/or scarcity of the elements used in a photovoltaic system has been published to date.

One aim of the present invention is, precisely, to provide alternative mineral compounds to those used in the current photovoltaic technologies, which make it possible to avoid the abovementioned problems.

To this end, the present invention proposes using a novel family of mineral materials, for which the inventors have now demonstrated, surprisingly, that they prove to have good efficacy, and that they have the advantage of not needing to use rare or toxic metals such as the abovementioned In, Te or Cd, and also offer the possibility of using anions, such as Se or Te in a reduced contents, or even of not using anions of this type.

More precisely, according to a first aspect, a subject of the present invention is the use of a material comprising at least one compound of formula (I):

BiCu_{1-z}OₐS_{b}Se_{c}Te_{d} (I)

in which 0≦z≦0.2 (for example, 0≦z≦0.1); 0≦a<2; 0≦b<2; 0≦c<2; 0≦d<2; and a+b+c+d=2;
as p-type semiconductor, to provide a photocurrent.

Preferentially, c=d=0 and a and b are non-zero, in which case the material contains at least one compound BiCu_{1-z}OₐS_{b}. According to an advantageous embodiment, z=0, a=1, b=1, c=0 and d=0, in which case the compound which is present in the mineral semiconductor material is typically BiCuOS.

In the context of the present invention, the inventors have now demonstrated that the materials corresponding to the abovementioned formula (I) are capable of providing a photocurrent when they are irradiated at a wavelength longer than their gap (namely the generation of an electron-hole pair in the material under the effect of an incident photon of sufficient energy, the charged species formed (the electron and the “hole”, namely the absence of an electron) being free to move to generate a current).

In particular, the inventors have now demonstrated that the materials of the invention appear to be capable of producing a photovoltaic effect.

In general, a photovoltaic effect is obtained via the combined use of two semiconductor compounds of different type, namely:
a first compound having semiconductor nature of p type; and
a second compound having semiconductor nature of n type.
   These compounds are placed close to each other in a manner known per se (i.e. in direct contact or at the very least at a distance that is small enough to ensure the photovoltaic effect) to form a junction of p-n type. The electron-hole pairs created by light absorption are dissociated at the p-n junction and the excited electrons may be conveyed by the n-type semiconductor to the anode, the holes being, themselves, conveyed to the cathode via the p-type semiconductor.

In the context of the invention, the photovoltaic effect is typically obtained by placing a semiconductor-based material of the abovementioned formula (I) in contact with an n-type semiconductor between two electrodes, in direct contact or optionally connected to at least one of the electrodes via an additional coating, for example a charge collector coating; and by irradiating the photovoltaic device thus made with suitable electromagnetic radiation, typically with light from the solar spectrum. To do this, it is preferable for one of the electrodes to allow passage of the electromagnetic radiation used.

According to a second particular aspect, a subject of the present invention is photovoltaic devices comprising, between a hole-conducting material and an electron-conducting material, a layer based on a compound of formula (I), especially based on BiCuOS, and a layer based on an n-type semiconductor, in which:
the layer based on the compound of formula (I) is in contact with the layer based on the n-type semiconductor;
the layer based on the compound of formula (I) is close to the hole-conducting material; and
the layer based on the n-type semiconductor is close to the electron-conducting material.

For the purposes of the present description, the term “hole-conducting material” means a material which is capable of circulating current between the p-type semiconductor and the electrical circuit.

The n-type semiconductor used in the photovoltaic devices according to the invention may be chosen from any semiconductor which has more pronounced electron-withdrawing nature than the compound of formula (I) or a compound which promotes the removal of electrons. Preferably, the n-type semiconductor may be an oxide, for example ZnO or TiO₂, or a sulphide, for example CdS.

The hole-conducting material used in the photovoltaic devices according to the invention may be, for example, a metal, for instance gold, tungsten or molybdenum; or a metal deposited on a support, such as Pt/FTO (platinum deposited on fluorine-doped tin dioxide); or a conductive oxide such as ITO (tin-doped indium oxide), for example deposited on glass; or a p-type conductive polymer.

According to a particular embodiment, the hole-conducting material may comprise a hole-conducting material of the abovementioned type and a redox mediator, for example an electrolyte containing the I₂/I⁻ couple, in which case the hole-conducting material is typically Pt/FTO.

The electron-conducting material may be, for example, FTO or AZO (aluminum-doped zinc oxide), or an n-type semiconductor.

In a photovoltaic device according to the invention, the holes generated at the p-n junction are extracted via the hole-conducting material and the electrons are extracted via the electron-conducting material of the abovementioned type.

In a photovoltaic device according to the invention, it is preferable for the hole-conducting material and/or the electron-conducting material to be a material that is at least partially transparent, which allows passage of the electromagnetic radiation used. In this case, the at least partially transparent material is advantageously placed between the source of the incident electromagnetic radiation and the p-type semiconductor.

To this end, the hole-conducting material may be, for example, a material chosen from a metal and a conductive glass.

Alternatively or in combination, the electron-conducting material may be at least partially transparent, and it is then chosen, for example, from FTO (fluorine-doped tin dioxide), AZO (aluminum-doped zinc oxide) and an n-type semiconductor.

According to another advantageous embodiment, the layer based on an n-type semiconductor which is in contact with the layer based on a compound of formula (I) may also be at least partially transparent.

The term “partially transparent material” means here a material which allows the passage of at least part of the incident electromagnetic radiation, useful for providing the photocurrent, and which may be:
a material that does not totally absorb the incident electromagnetic field; and/or
a material that is in a perforated form (typically comprising holes, slits or interstices) capable of allowing the passage of part of the electromagnetic radiation without this radiation encountering the material.

The compound of formula (I), especially BiCuOS, used according to the present invention is advantageously used in the form of isotropic or anisotropic objects having at least one dimension of less than 50 μm, preferably less than 20 μm, typically less than 10 μm, preferentially less than 5 μm, generally less than 1 μm, more advantageously less than 500 nm, for example less than 200 nm, or even 100 nm.

Typically, the dimension less than 50 μm may be:
the mean diameter in the case of isotropic objects;
the thickness or the transverse diameter in the case of anisotropic objects.

According to a first variant, the objects based on a compound of formula (I) are particles, typically having dimensions of less than 10 μm. This mode is especially advantageous when the compound of formula (I) is BiCuOS.

The term “particles” means here isotropic or anisotropic objects, which may be individual particles, or aggregates.

The dimensions of the particles to which reference is made here may typically be measured by scanning electron microscopy (SEM).

Advantageously, the compound of formula (I) is in the form of anisotropic particles of platelet type, or of agglomerates of a few dozen to a few hundred particles of this type, these platelet-type particles typically having dimensions that remain less than 5 μm (preferentially less than 1 μm and more advantageously less than 500 nm), with a thickness that typically remains less than 500 nm, for example less than 100 nm.

The particles of the type described according to the first variant may typically be used in the form deposited on an n-type conductive or semiconductor support.

An ITO or metal plate covered with particles according to the invention may thus, for example, act as a photoactive electrode for a device of photoelectrochemical type that may be used especially as a photodetector.

Typically, a device of photoelectrochemical type using a photoactive electrode of the abovementioned type comprises an electrolyte that is generally a salt solution, for example a KCl solution, typically having a concentration of about 1 M, in which are immersed:
a photoactive electrode of the abovementioned type (ITO or metal plate covered with particles of compound of formula (I) according to the invention);
a reference electrode; and
a counter-electrode;
   these three electrodes being linked together, typically via a potentiostat.

According to a possible embodiment, the electrochemical device may comprise:
as photoactive electrode: a support (such as an ITO plate) covered with BiCuOS particles;
as reference electrode: for example, an Ag/AgCl electrode; and
as counter-electrode: for example, a platinum wire;
   these three electrodes being linked together, typically via a potentiostat.

When an electrochemical device of this type is placed under a light source, under the effect of irradiation, electron-hole pairs form and are dissociated.

When the electrolyte is an aqueous solution, which is usually the case, the water in the electrolyte is reduced close to the photoactive electrode by the electrons generated, producing hydrogen and OH⁻ ions. The OH− ions thus produced migrate toward the counter-electrode via the electrolyte; and the holes of the compound of formula (I) are extracted via the ITO-type conductor and enter the external electrical circuit. Finally, the oxidation of the OH⁻ ions is performed using holes close to the counter-electrode, producing oxygen. The placing in motion of these charges (holes and electrons), induced by the absorption of light of the compound of formula (I), generates a photocurrent.

The device may especially be used as a photodetector, the photocurrent being generated only when the device is illuminated.

A photoactive electrode as described above may especially be prepared using a suspension, comprising particles of a compound of formula (I) of the abovementioned type dispersed in a solvent, and placing this suspension on a support, for example a glass plate covered with ITO or a metal plate, via the wet route or any coating method, for example by drop-casting, spin-coating, dip-coating, ink-jet printing or screen printing. For further details regarding this subject, reference may be made to the article: R. M. Pasquarelli, D. S. Ginley, R. O'Hayre, in Chem. Soc. Rev., vol 40, pp. 5406-5441, 2011. Preferably, the particles based on a compound of formula (I) which are present in the suspension have a mean diameter as measured by laser granulometry (for example using a Malvern laser granulometer) which is less than 5 μm.

According to a preferential embodiment, the particles of compound of formula (I) may be predispersed in a solvent, for example terpineol or ethanol.

The suspension containing the particles of compound of formula (I) may be deposited on a support, for example a plate covered with conductive oxide.

Particles of BiCu_{1-z}OₐS_{b}Se_{c}Te_{d}, for example of BiCuOS, which are well suited to the implementation of the invention may typically be obtained according to a process comprising a heat treatment of a mixture of mineral compounds in dissolved, dispersed or divided form (typically in the form of a solution or a powder), comprising:
bismuth and copper compounds (and optionally tellurium compounds, which lead to compounds in which d>0), comprising
a source of oxygen (preferably including at least one bismuth or copper oxide) and a source of sulphur (and optionally a source of selenium, which leads to compounds in which c>0),
   whereby particles of BiCu_{1-z}OₐS_{b}Se_{c}Te_{d} are formed, which are generally recovered after a cooling operation following the heat treatment.

The heat treatment may advantageously be performed
by treating under hydrothermal conditions, preferably with stirring, the mineral compounds in dissolved form in water, the dissolution possibly being performed during the hydrothermal treatment for all or part of the mineral compounds and/or prior to the hydrothermal treatment for all or part of the organic compounds;
   or
by treating at a temperature of at least 500° C. (preferably from about 520 to 600° C., for example about 550° C.) a mixture of the compounds in the form of a solid powder.

Particles of BiCu_{1-z}OₐS_{b}, for example of BiCuOS, with dimensions of less than 5 μm, which are well suited to the implementation of the invention, may typically be obtained according to a process comprising the following steps:

(a) supplying a mixture of bismuth and copper mineral compounds in dispersed form preferably comprising at least one bismuth or copper oxide, and a source of sulphur;

(b) dissolving the mixture in water or an aqueous medium under hydrothermal conditions and preferably with stirring; and

(c) cooling the solution obtained, whereby particles of BiCu_{1-z}OₐS_{b} are formed.

This specific process, which leads to suspensions containing particles of reduced dimensions, also constitutes, according to yet another aspect, a particular subject of the invention.

More generally, particles of BiCu_{1-z}OₐS_{b}Se_{c}Te_{d} of formula (I) with dimensions of less than 5 μm, which are well suited to the implementation of the invention, may typically be obtained according to a process comprising the following steps:

(a′) supplying a mixture of bismuth and copper mineral compounds in dispersed form (and, where appropriate, of tellurium compounds, which leads to compounds in which d>0) preferably comprising at least one bismuth or copper oxide, a source of sulphur and, where appropriate, a source of selenium (which leads to compounds in which c>0);

(b′) dissolving the mixture in water or an aqueous medium under hydrothermal conditions and preferably with stirring; and

(c′) cooling the solution obtained, whereby particles of BiCu_{1-z}OₐS_{b}Se_{c}Te_{d} are formed.

The aqueous medium used in steps (a) and (a′) may especially be a solvent, for example a mixture of ethylene glycol or an ionic liquid at reflux.

Optionally, after step (c) or (c′), a deagglomeration step may be performed, for example with an ultrasonication probe.

The bismuth and copper mineral compounds supplied in the mixture of step (a) or (a′) are, for example, Bi₂O₃ and Cu₂O. According to another possible embodiment, bismuth and copper soluble salts may be used. In particular, in the case of absence of oxide of the mineral compounds in step (a) (and, respectively, (a′)), step (b) (and, respectively, (b′)) is advantageously performed in the presence of a source of oxygen, such as water, nitrates or carbonates.

The mineral tellurium compound in the mixture of step (a′) is, for example, tellurium, tellurium oxide or a tellurium salt.

The source of sulphur used in steps (a) and (a′) may be chosen from sulphur, hydrogen sulphide H₂S and salts thereof, an organosulphur compound (thiol, thioether, thioamide, etc.), preferably an anhydrous or hydrated sodium sulphide.

The source of selenium used in step (a′) may be chosen from selenium, selenium oxide and a selenium salt, for example Na₂Se.

Preferentially, irrespective of their exact nature, the oxides in dispersed form are used in steps (a) and (a′) in the form of particles, typically in the form of powders, having a particle size of less than 5 μm, typically less than 1 μm and preferentially less than 500 nm. This particle size may be obtained, for example, by premilling the oxides (separately or, more advantageously in the case of mixtures of oxides, this milling may be performed on the mixture of oxides), for example using a device such as a micronizer or wet ball mill.

In steps (b) and (b′), the dissolution is performed under “hydrothermal conditions”. For the purposes of the present description, this term means that the step is performed at a temperature above 180° C. under the saturating vapor pressure of water.

When milling is performed, the temperature of step (b) or (b′) may be less than 240° C., or even less than 210° C., for example between 180° C. and 200° C.

Alternatively, step (b) or (b′) may be performed without premilling, in which case it is, however, preferable to perform the step at a temperature above 240° C., preferably above 250° C.

Preferably, in steps (b) and (b′), the mixture is placed in water at a temperature below the hydrothermal conditions (typically at room temperature and at atmospheric pressure), and the temperature is then raised slowly, advantageously at a rate of less than 10° C./minute, for example between 0.5 and 5° C./minute, typically at 2.5° C./minute, typically operating in a closed medium (using a device such as a hydrothermal bomb, especially a Parr bomb) until the operating temperature is reached.

In steps (b) and (b′), the dissolution is specifically performed with stirring. This stirring may especially be performed by magnetic stirring, for example by placing the hydrothermal bomb on a magnetic stirrer, the assembly being placed in a heating chamber (such as an oven).

Steps (b) and (b′) are performed for a time sufficient to obtain dissolution. Typically, the temperature is maintained at at least 190° C. for at least 12 hours, for example for 48 hours, or even 7 days.

After the dissolution performed in steps (b) and (b′), in steps (c) and (c′), the solution obtained is typically brought to room temperature or more generally to a temperature of between 10 and 30° C. by cooling, for example by reducing the temperature at a rate of at least 1° C./minute, preferably by more rapid cooling, with a decrease typically of at least 3° C./minute, for example from 3 to 5° C./minute. This type of cooling typically leads to particles with a length of between 50 nm and 5 μm, typically between 100 nm and 1 μm, and a thickness of 50 nm. Moreover, without wishing to be bound to a particular theory, the abovementioned high cooling rates generally lead to very low contents of impurities (especially Cu₂S, Bi₂O₃ and Cu₃BiS₃).

Alternatively, particles of BiCu_{1-z}OₐS_{b}Se_{c}Te_{d} of formula (I) with dimensions of less than 5 μm, which are well suited to the implementation of the invention, may be obtained according to a process comprising the following steps:
supplying an aqueous solution of mineral compounds comprising:
   bismuth and copper compounds (and optionally of tellurium, which leads to compounds in which d>0), comprising
   a source of oxygen (preferably including at least one bismuth or copper oxide) and a source of sulphur (and optionally a source of selenium, which leads to compounds in which c>0),
treating the solution under hydrothermal conditions, preferably with stirring; and
cooling the solution obtained, whereby particles of BiCu_{1-z}OₐS_{b}Se_{c}Te_{d} are formed.

Another envisageable process, which leads to particles of BiCu_{1-z}OₐS_{b}Se_{c}Te_{d} of formula (I), which are well suited to the implementation of the invention, typically with dimensions of less than 5 μm, comprises the following steps:
supplying a solid mixture of mineral compounds in divided form (typically in powder form) comprising:
   bismuth and copper compounds (and optionally of tellurium, which leads to compounds in which d>0), comprising
   a source of oxygen (preferably including at least one bismuth or copper oxide) and a source of sulphur (and optionally a source of selenium, which leads to compounds in which c>0),
treating the solid mixture at a temperature of at least 500° C. (preferably from about 520 to 600° C., for example about 550° C.), whereby particles of BiCu_{1-z}OₐS_{b}Se_{c}Te_{d} are formed (which are then recovered typically after cooling).

According to a second variant of the invention, which proves to be well suited to producing photovoltaic devices, the compound of formula (I) is in the form of a continuous layer based on the compound of formula (I), whose thickness is less than 50 μm, preferably less than 20 μm, more advantageously less than 10 μm, for example less than 5 μm and typically greater than 500 nm. In this second variant, the compound of formula (I) may especially be BiCuOS.

The term “continuous layer” means here a homogeneous deposit produced on a support and covering said support, not obtained by simple deposition of a dispersion of particles onto the support.

The continuous layer based on a compound of formula (I) according to this particular variant of the invention is typically placed close to a layer of an n-type semiconductor, between a hole-conducting material and an electron-conducting material, to form a photovoltaic device intended to provide a photovoltaic effect.

An n-type semiconductor in the use according to the invention may be a conductive oxide, for example ZnO or TiO₂, or a sulphide, for example CdS.

Moreover, the term layer “based on the compound of formula (I)” means a layer comprising compound of formula (I), preferably in a proportion of at least 50% by mass, or even in a proportion of at least 75% by mass.

According to one embodiment, the continuous layer according to the second variant consists essentially of compound of formula (I), and it typically comprises at least 95% by mass, or even at least 98% by mass and more preferentially at least 99% by mass of the compound of formula (I).

The continuous layer based on a compound of formula (I) used according to this embodiment may take several forms:
Variant 1: the continuous layer is a continuous layer based on a compound of formula (I) deposited on a support.

Typically, according to this variant, the layer consists essentially of the compound of formula (I).

The continuous layer may typically be obtained:
electrochemically:
   In general, electrochemical deposition comprises the following steps:

(1a) the support (as cathode) is immersed in a bath of electrolyte containing copper and bismuth ions and optionally tellurium ions, and a counter-electrode (as anode), and, on passing an electrical current between the two electrodes, deposition of an alloy based on Bi and Cu, and optionally Te, is induced on the support;

(1b) the support covered with the alloy obtained after step (1a) is reacted under an atmosphere containing a source of oxygen, and/or a source of sulphur and/or a source of selenium.

The thickness of the layer obtained on the support may be very readily controlled, namely by simple modulation of the electrodeposition operating time (the longer the current is allowed to circulate, the greater the thickness of the layer).
by physical deposition, especially by cathodic sputtering or magnetron cathodic sputtering):
   In general, deposition by cathodic sputtering or magnetron cathodic sputtering comprises the following steps:

(2a) a support is placed in a chamber of a deposition reactor under vacuum;

(2b) a potential difference is applied between one or more targets containing Bi and Cu and optionally tellurium, and the walls of the reactor, where a plasma created bombards the target, the elements of which are ejected and condense on the support to form an alloy based on Bi and Cu, and optionally Te;

(2c) the support covered with the alloy obtained after step (2b) is reacted under an atmosphere containing a source of oxygen, and/or a source of sulphur and/or a source of selenium. For a chosen deposition condition (it is generally the optimized condition), the thickness of the layer may be controlled by the deposition time, the longer the deposition time, the greater the thickness of the layer.
by co-evaporation:
   In general, deposition by co-evaporation comprises the following steps:

(3a) copper and bismuth and optionally Te metal elements are simultaneously evaporated under vacuum on a support to form an alloy based on Bi and Cu, and optionally Te;

(3b) the support covered with the alloy obtained after step (3a) is reacted under an atmosphere containing a source of oxygen, and/or a source of sulphur and/or a source of selenium.

The thickness of the layer may be controlled by the evaporation time, namely, the longer the deposition time, the greater the thickness of the layer.

The source of sulphur used in step (1b) or (2c) or (3b) may be chosen from sulphur, hydrogen sulphide H2S and salts thereof, an organosulphur compound (thiol, thioether, thioamide, etc.).

The source of selenium used in steps (1b), (2c) and (3b) may be chosen from selenium, selenium oxide and a selenium salt, for example Na₂Se.

The support onto which is deposited the compound of formula (I) of the abovementioned layer type according to the invention may be, for example, an n-type conductive or semiconductor material.
Variant 2: the continuous layer comprises a polymer matrix and, dispersed in this matrix, particles based on a compound of formula (I), typically with dimensions of less than 10 μm, or even less than 5 μm, especially of the type used in the first embodiment of the invention.

Typically, the polymer matrix comprises a p-type conductive polymer, which may be chosen especially from polythiophene derivatives, more particularly from poly(3,4-ethylenedioxythiophene):poly(styrenesulphonate) (PEDOT:PSS) derivatives.

The particles based on the compound of formula (I) present in the polymer matrix preferably have dimensions of less than 5 μm, which may especially be determined by SEM.

In certain cases, the dispersion of the particles in the polymer matrix enables a size analysis by laser granulometry: where appropriate, the mean particle diameter is generally less than 5 μm.

The invention will now be illustrated in greater detail with reference to the illustrative examples given below and in the attached figures, in which:

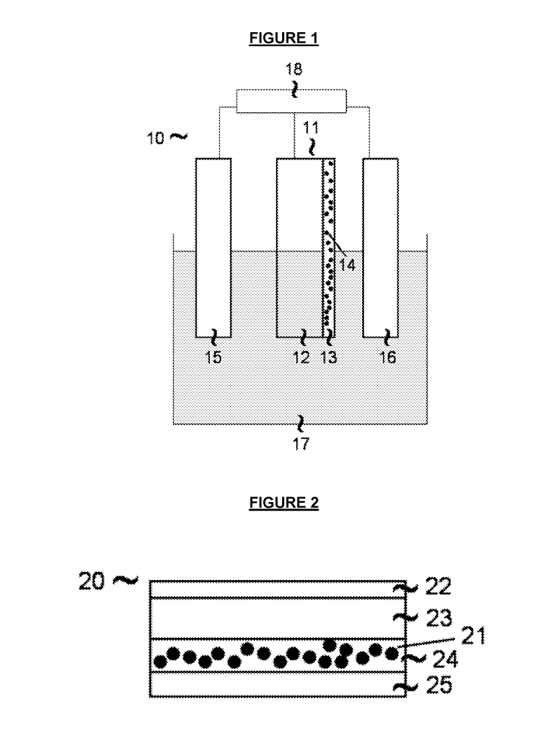

FIG. 1 is a schematic representation in cross section of a photoelectrochemical cell used in example 2 described below;

FIG. 2 is a schematic representation in cross section of the photodetector device used in example 3;

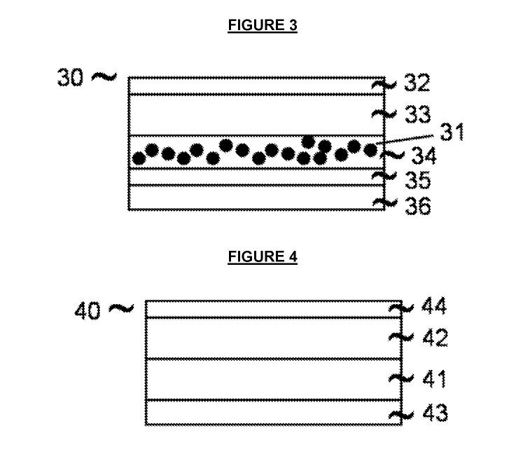

FIG. 3 is a schematic representation in cross section of the photovoltaic device used in example 4;

FIG. 4 is a schematic representation in cross section of a photovoltaic device according to the invention, not illustrated.

FIG. 1 shows a photoelectrochemical cell 10 which comprises:
a photoactive electrode 11 consisting of a support 12 based on a glass covered with a conductive layer of ITO of 2 cm×1 cm onto which has been deposited over the entire surface a layer 13 about 1 μm thick based on particles 14 of BiCuOS prepared according to the protocol of example 1 described below, the particles 14 of BiCuOS were predispersed in terpineol and then deposited by coating (doctor blade coating) onto the conductive glass plate 11;
an (Ag/AgCl) reference electrode 15; and
a counter-electrode (platinum wire) 16.
   The three electrodes 11, 15 and 16 are immersed in an electrolyte 17 of 1M KCl. The three electrodes are linked via a potentiostat 18.

FIG. 2 shows a photodetector device 20 which comprises particles 21 of BiCuOS prepared under the conditions of example 1 described below. This device comprises an FTO layer 22 about 500 nm thick onto which is electro-deposited a layer 23 about 1 μm thick based on ZnO. Layer 24 about 1 μm thick based on particles 21 of BiCuOS is deposited on the surface of layer 23 by deposition of the drops from a suspension of BiCuOS at 25-30% by mass in ethanol. A gold layer 25 about 1 μm thick is deposited on layer 24 by evaporation.

FIG. 3 shows the photovoltaic device 30 which comprises particles 31 of BiCuOS prepared under the conditions of example 1 described below. This device comprises an FTO layer 32 about 500 nm thick onto which is electro-deposited a layer 33 about 1 μm thick based on ZnO. Layer 34 about 1 μm thick based on particles 31 of BiCuOS is deposited on the surface of layer 33 by deposition of the drops from a suspension of BiCuOS at 25-30% by mass in ethanol. An electrolyte containing the I₂I⁻ couple 35 serving as redox mediator is deposited by deposition of the drops onto the surface of layer 34, and on which a gold layer 36 about 1 μm thick is deposited by evaporation.

FIG. 4 shows the photovoltaic device which comprises a layer 41 based on BiCuOS deposited onto a layer 42 based on ZnO by coating, layer 42 based on ZnO being prepared by sol-gel deposition, layer 41 based on BiCuOS being in contact with a gold layer 43 and layer 42 based on ZnO being in contact with an FTO layer 44.

The placing in contact of the BiCuOS with an n-type semiconductor ZnO forms a p-n junction. When the device is placed under a light source, the electrons generated move into the ZnO and the holes generated remain in the BiCuOS. The ZnO is in contact with FTO (electron conductor) to extract the electrons therefrom and the BiCuOS is in contact with gold (hole conductor) to extract the holes therefrom.

### EXAMPLES

### Example 1

### Process for Preparing BiCuOS Particles Via the Hydrothermal Route

A BiCuOS powder was prepared via the hydrothermal route, according to the following protocol:
429 mg of Bi₂O₃ (purity>99.8%), 132 mg of Cu₂O (purity>99%) and 442 mg of Na₂S, 9H₂O (purity>98%) are milled:
the milled oxides are placed in a Teflon shell with 75 ml of water (milliQ grade);
the Teflon shell is placed in a 125 ml Parr bomb and the assembly is placed in a heating chamber;
the system is stirred magnetically and this stirring is maintained;
   the chamber temperature is raised from 25° C. to 190° C. at a rate of 2.5° C./minute;
   the temperature is left at 190° C. for 2 days;
   the system is then returned to room temperature at a rate of 3° C./minute, to give a suspension.
the suspension obtained is filtered, washed with three times 100 ml of water (milliQ grade) and then with three times 50 mL of hydrochloric acid solution at 4% by mass, and then washed again with three times 100 ml of water (milliQ grade).
the solid obtained is dried at 80° C. in an oven for 2 hours.

### Example 2

### Process for Preparing BiCuOS Particles Via the Hydrothermal Route (With Predissolution)

A BiCuOS powder was prepared via the hydrothermal route by dissolving the mineral precursors in the form of a solution S prior to the hydrothermal treatment, according to the following protocol:

### Preparation of a Solution S1 Based on Bismuth Compounds

bismuth nitrate is dissolved at 0.2 M in aqueous 5% by mass HNO₃ solution.

50 ml of the solution obtained are added slowly to 50 ml of a solution containing 15 g of NaOH and 0.2 M of tartaric acid, to give a solution S1.

Preparation of a Solution S2 based on Copper (I) Compounds

1 ml of aqueous ammonia at 28% by mass is added dropwise with stirring to 50 ml of aqueous 0.2 M copper (II) sulphate solution, to give a deep blue solution;

50 ml of aqueous 1M sodium thiosulphate solution are added dropwise with stirring to the solution thus obtained, to give a colorless solution S2.

Preparation of solution S

solutions S1 (25 ml) and S2 (25 ml) are mixed, to form a transparent solution, and 25 ml of 0.1 M Na₂S solution are then added, to form solution S (black).

### Preparation of the Particles

75 ml of solution S are placed in a Teflon shell;

the Teflon shell is placed in a 125 ml Parr bomb and the assembly is placed in a heating chamber;

the system is stirred magnetically and this stirring is maintained;

the chamber temperature is raised from 25° C. to 240° C. at a rate of 2.5° C./minute;

the temperature is left at 240° C. for 2 days;

the system is then returned to room temperature at a rate of 3° C./minute, to give a suspension.

the suspension obtained is filtered, washed with three times 100 ml of water (milliQ grade) and then with three times 50 mL of hydrochloric acid solution at 4% by mass, and then washed again with three times 100 mL of water (milliQ grade).

the solid obtained is dried at 80° C. in an oven for 2 hours.

### Example 3

### Process for Preparing BiCuOS Particles Via the Solid Route

A BiCuOS powder was prepared via the solid route, according to the following protocol:
the following are milled in a mortar:
   8.224 g of Bi₂S₃ (purity>99.9%),
   14.912 g of Cu₂S (purity>99.5%) and
   7.632 g of Bi₂O₃ (purity>98%) until a homogeneous mixture is obtained;
the powder mixture obtained is mixed for 1 hour in a turbulator;
the mixture is then placed in a 200 cm³ silica tube, the tube is placed under vacuum and sealed, and is then placed in an oven at 550° C. for 2 days (calcination);
after the calcination, a black powder, which is extracted from the sealed tube once cooled, is obtained.

### Example 4

### Use of the BiCuOS of Example 1 in a Photoelectrochemical Device

The device described in FIG. 1 was used, by polarizing the working electrode at a potential of −0.8 V vs Ag/AgCl. The system is irradiated under an incandescent lamp (color temperature of 2700 K) alternating periods of darkness and periods of lighting. The intensity of the current increased when the system was placed in light. This is a photocurrent, which confirms the capacity of BiCuOS to generate a photocurrent. This photocurrent is cathodic (i.e. negative), which is in agreement with the fact that BiCuOS is a p-type semiconductor.

### Example 5

### Use of the BiCuOS of Example 1 in a Photodetector Device

The device described in FIG. 2 was used, in which a p-n junction is made between BiCuOS and ZnO. The ZnO is in contact with FTO to extract the electrons therefrom and the BiCuOS is in contact with gold to extract the holes therefrom. A significant increase in current (of 1.1 mA/cm² at 1 V) is observed when the system is placed in irradiated light under an incandescent lamp (color temperature of 2700 K).

### Example 6

### Use of the BiCuOS of Example 1 in a Photovoltaic Device

The device described in FIG. 3 was used, irradiated under an incandescent lamp (color temperature of 2700 K). The I₂/I⁻ redox couple is used as redox mediator to transport the holes. The counter-electrode is platinum. The characteristic parameters of the photovoltaic cell are as follows: V_{oc}=39 mV; J_{sc}=1.5 μA.cm⁻².

1. A method for providing photocurrent, the method comprising using a material comprising at least one compound of formula (I):
BiCu_{1-z}OₐS_{b}Se_{c}Te_{d} (I)
in which 0≦z≦0.2; 0≦a<2; 0≦b<2; 0≦c<2; 0≦d<2; and a+b+c+d=2;
as p-type semiconductor, to provide a photocurrent.

2. The method of claim 1, in which z=0, a=1, b=1, c=0 and d=0.

3. The either method of claim 1, in which the compound of formula (I) is used in the form of isotropic or anisotropic objects having at least one dimension of less than 50 μm.

4. The method of claim 3, in which the compound of formula (I) is used in the form of particles with dimensions of less than 10 μm.

5. The method of claim 4, in which the compound of formula (I) is in the form of anisotropic particles of platelet type, or of agglomerates of a few dozen to a few hundred particles of this type.

6. The method of claim 3, in which the compound of formula (I) is in the form of a continuous layer based on a compound of formula (I) whose thickness is less than 50 μm, in which the layer based on a compound of formula (I) is a layer comprising compound of formula (I) in a proportion of at least 95% by mass.

7. The method of claim 3, in which the compound of formula (I) is in the form of a continuous layer based on a compound of formula (I) whose thickness is less than 50 μm, in which the layer based on a compound of formula (I) comprises a polymer matrix and, dispersed in this matrix, particles based on a compound of formula (I) with dimensions of less than 5 μm.

8. A process for preparing particles of the compound of formula (I) used according to the method of claim 1, the process comprising a heat treatment of a mixture of mineral compounds in dissolved, dispersed or divided form, said mixture comprising:
bismuth and copper compounds, and optionally tellurium compounds; and
a source of oxygen, a source of sulphur, and optionally a source of selenium,
whereby particles of the compound of formula (I) are formed.

9. A process for preparing particles with dimensions of less than 5 μm based on BiCu_{1-z}OₐS_{b} in which 0≦z≦0.2; 0≦a<2; 0≦b<2 which process comprises the following steps:
(a) supplying a mixture of bismuth and copper mineral compounds in dispersed form, and a source of sulphur;
(b) dissolving the mixture in water or an aqueous medium under hydrothermal conditions; and
(c) cooling the solution obtained, whereby particles of BiCu_{1-z}OₐS_{b} are formed.

10. A photovoltaic device comprising, between a hole-conducting material and an electron-conducting material, a layer based on a compound of formula (I):
BiCu_{1-z}COₐS_{b}Se_{c}Te_{d} (I)
in which 0≦z≦0.2; 0≦a<2; 0≦b<2; 0≦c<2; 0≦d<2; and a+b+c+d=2, and a layer based on an n-type semiconductor, in which:
the layer based on the compound of formula (I) is in contact with the layer based on the n-type semiconductor;
the layer based on the compound of formula (I) is close to the hole-conducting material; and
the layer based on the n-type semiconductor is close to the electron-conducting material.

11. The method of claim 3, in which the compound of formula (I) is used in the form of isotropic or anisotropic objects having at least one dimension of less than 20 μm.

12. The method of claim 6, wherein the thickness is less than 20 μm.

13. The method of claim 7, wherein the thickness is less than 20 μm.

14. The process of claim 8, wherein the source of oxygen includes at least one bismuth or copper oxide.

15. The process of claim 8, wherein the particles of the compound of formula (I) that are formed are recovered after a cooling operation subsequent to the heat treatment.

16. The process of claim 9, wherein the mixture of bismuth and copper mineral compounds in dispersed form comprise at least one bismuth or copper oxide.

17. The process of claim 9, wherein the mixture is dissolved in water or an aqueous medium under hydrothermal conditions with stirring.

18. The photovoltaic device of claim 10, wherein the layer based on a compound of formula (I) is a layer based on BiCuOS.
